(19) United States
(12) Patent Application Publication
(10) Pub. No.: US 2010/0022080 A1
(43) Pub. Date: Jan. 28, 2010

(54) METHOD OF MANUFACTURING SEMICONDUCTOR DEVICE

(75) Inventors: Sekikin Sho, Kawasaki (JP); Kazuto Ikeda, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/568,751

(22) Filed: Sep. 29, 2009

Related U.S. Application Data
(63) Continuation of application No. PCT/JP2007/057114, filed on Mar. 30, 2007.

(51) Int. Cl. H01L 21/28

(52) U.S. Cl. 438/591; 257/E21.193

(57) ABSTRACT

The method of manufacturing the semiconductor device includes nitridizing a silicon substrate with ammonia while heating the silicon substrate, then heating the silicon substrate in an atmosphere containing nitrogen and oxygen to form a gate insulating film including a silicon-based insulating film containing nitrogen and oxygen, then annealing the silicon substrate in an oxygen atmosphere, and forming a gate electrode on the gate insulating film.

### CROSS-REFERENCE TO RELATED APPLICATIONS

This application is a Continuation of International Application No. PCT/JP2007/057114, with an international filing date of Mar. 30, 2007, which designating the United States of America, the entire contents of which are incorporated herein by reference.

### FIELD

The embodiments discussed herein are related to a method of manufacturing a semiconductor device, more specifically, a method of manufacturing a semiconductor device including a gate insulating film of a nitrogen-content silicon-based insulating film.

### BACKGROUND

The high speed and integration of the LSI has been advanced by downsizing the Metal-Insulator-Semiconductor Field Effect Transistor (hereinafter called MISFET) in accordance with the scaling law. That is, the height-wise and the transverse sizes of the respective parts of the MISFET, such as the film thickness of the gate insulating film, the gate length, etc., are concurrently reduced, whereby the characteristics of the downsized device has been retained normal, and achievement of the device has been enhanced. At present the MISFET is still being downsized, and the next generation MISFET requires a gate insulating film of a film thickness of not more than the effective thickness corresponding to 1 nm of the silicon oxide film.

Conventionally, as the gate insulating film, the silicon oxide film has been widely used. However, the problem that when the silicon oxide film has a film thickness of about not more than 3 nm, the tunnel leakage current becomes conspicuous, and the silicon oxide film does not function as the insulating film has been pointed out. The problem that with the gate insulating film thinned, the dopant impurity doped in the gate electrode passes through the gate insulating film and diffuses into the channel region of the silicon substrate, and the MIS characteristics are changed has been pointed out.

As means of decreasing the leakage current and the pass-through of the dopant impurity, the use of silicon oxynitride film formed of silicon oxide film with nitrogen added to is used as the gate insulating film is proposed.

For example, Japanese Laid-open Patent Publication No. 06-029314 discloses the technique that nitrogen is ion-implanted into at least one of the gate electrode and the silicon substrate, and into the gate insulating film, whereby the characteristics of the interface between the silicon substrate and the gate insulating film are improved without increasing the film thickness of the gate insulating film and causing the degradation of the insulation.

Japanese Laid-open Patent Publication No. 2004-022902 discloses the technique that a silicon oxide film and a silicon nitride film are formed on a silicon substrate and then plasma nitridation processing and heat processing in a non-oxidizing gas atmosphere are made, whereby the segregation of the nitrogen in the interface between the silicon substrate and the insulating film is suppressed to thereby increase the MIS capacitance and decrease the leakage current.

Japanese Laid-open Patent Publication No. 2006-019366 discloses the technique that a silicon oxide film is formed on a silicon substrate, and then in a vacuum vessel, UV irradiation, and nitridation processing or oxynitridation processing are made, whereby the segregation of the nitrogen in the interface between the silicon substrate and the insulating film is suppressed while the vicinity of the surface alone is heavily nitridized to thereby form a gate insulating film of high reliability.

The following is another example of related art of the present invention: International Publication Pamphlet No. WO 2004/097922.

Accompanying the downsizing of the MISFET, the physical film thickness of the gate insulating film of the 65 nm generation and the 45 nm generation has been not more than 1.2 nm. Accordingly, to prevent the diffusion of the dopant impurity from the gate electrode and the decrease the leakage current from the gate electrode, the nitrogen concentration to be introduced into the gate insulating film becomes increasingly higher. However, silicon oxynitride film of such high nitrogen concentration often increases the leakage current due to the charge increase in the interface between the silicon oxide film and the silicon oxynitride film or in the silicon oxynitride film.

As the film thickness of the gate insulating film decreases, the oxygen concentration in the film forming atmosphere is decreased so as to enable the film forming control. Resultantly, defects due to the oxygen shortage are often introduced in the film forming the gate insulating film.

### SUMMARY

According to one aspect of an embodiment, there is provided a method of manufacturing a semiconductor device including nitridizing a silicon substrate with ammonia while heating the silicon substrate, then heating the silicon substrate in an atmosphere containing nitrogen and oxygen to form a gate insulating film including a silicon-based insulating film containing nitrogen and oxygen, then annealing the silicon substrate in an oxygen atmosphere, and forming a gate electrode on the gate insulating film.

According to another aspect of an embodiment, there is provided a method of manufacturing a semiconductor device including nitridizing a silicon substrate with ammonia while heating the silicon substrate, then annealing the silicon substrate in an oxygen atmosphere, then heating the silicon substrate in an atmosphere containing nitrogen and oxygen to form a gate insulating film including a silicon-based insulating film containing nitrogen and oxygen, and forming a gate electrode on the gate insulating film.

According to further another aspect of an embodiment, there is provided a method of manufacturing a semiconductor device including forming a silicon oxide film over a silicon substrate, forming a silicon nitride film over the silicon oxide film, then annealing the silicon substrate in an oxygen atmosphere to form a gate insulating film including a silicon-based insulating film containing nitrogen and oxygen, and forming a gate electrode on the gate insulating film, annealing the silicon substrate being made at a temperature of 400° C.-850° C. in an atmosphere of a 0.03 Torr-90 Torr oxygen partial pressure.

The object and advantages of the embodiment will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIGS. 1A-1D and 2A-2C are sectional views illustrating a method of manufacturing a semiconductor device according to a first embodiment;

FIG. 3 is a view illustrating the temperature profile of the process for forming the gate insulating film in the method of manufacturing the semiconductor device according to the first embodiment;

FIG. 4 is a graph illustrating the relationships between the gate leakage current and the effective film thickness converted to silicon oxide film of samples with oxygen anneal and samples without oxygen anneal;

FIG. 5 is a graph illustrating changes of the flat band voltage depending on the absence and presence of oxygen anneal;

FIG. 6 is a view illustrating the temperature profile of the process for forming the gate insulating film in the method of manufacturing the semiconductor device according to a modification of the first embodiment;

FIGS. 7A-7D are sectional views illustrating a method of manufacturing a semiconductor device according to a second embodiment;

FIG. 8 is a view illustrating the temperature profile of the process for forming the gate insulating film of the method of manufacturing the semiconductor device according to a second embodiment;

FIG. 9 is a graph illustrating changes of the gate leakage current depending on the absence and presence of oxygen anneal;

FIG. 10 is a graph illustrating the cumulative probability distribution of the TDDB lifetimes of the gate insulating film of samples with oxygen anneal and samples without oxygen anneal;

FIGS. 11A-11D are sectional views illustrating a method of manufacturing a semiconductor device according to a third embodiment; and

FIG. 12 is a view illustrating the temperature profile of the process for forming the gate insulating film of the method of manufacturing the semiconductor device according to the third embodiment.

### DESCRIPTION OF EMBODIMENTS

### A First Embodiment

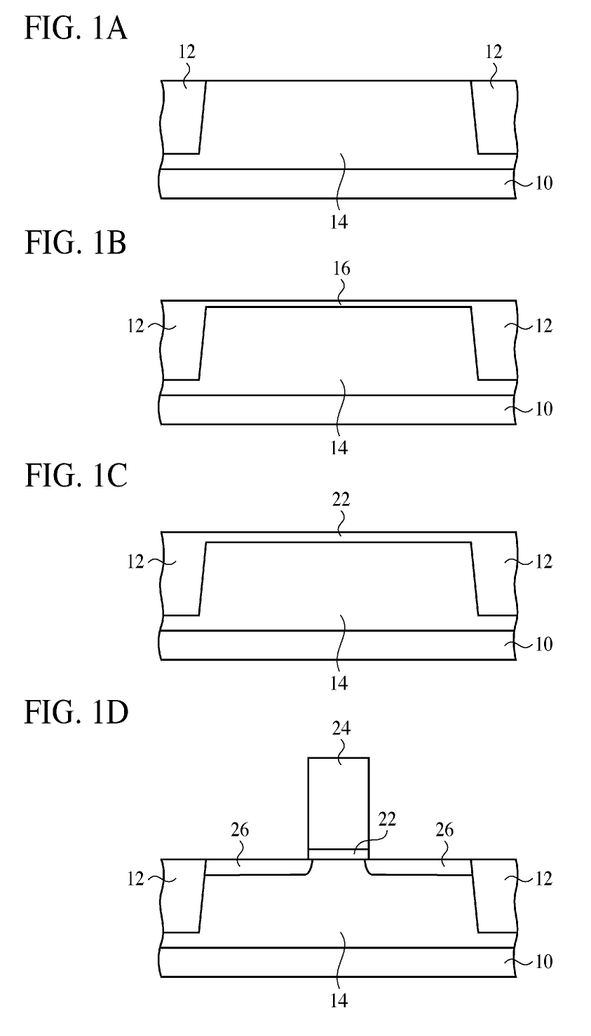

The method of manufacturing the semiconductor device according to a first embodiment will be explained with reference to FIGS. 1A to 6.

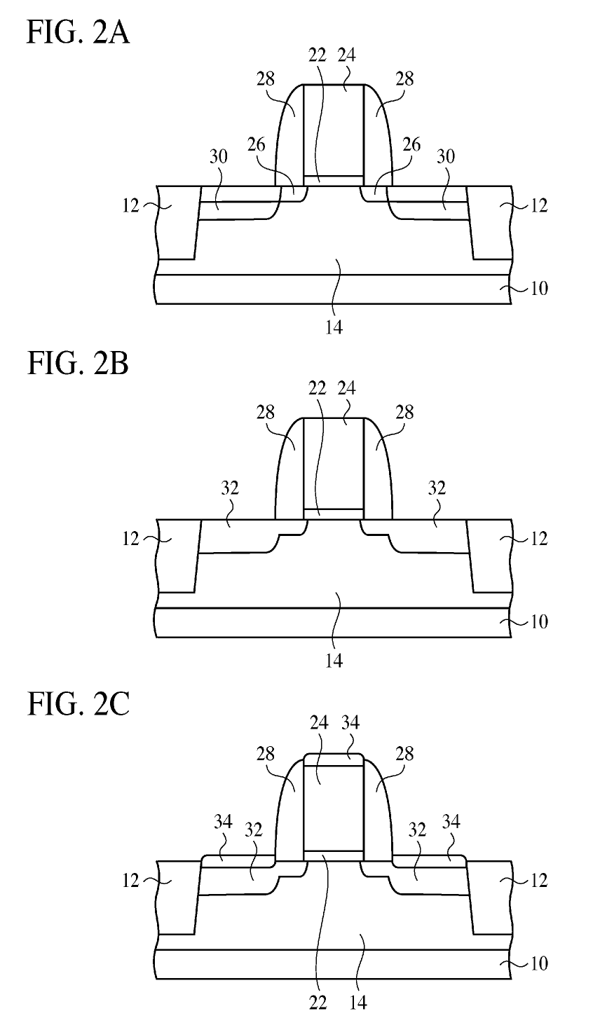

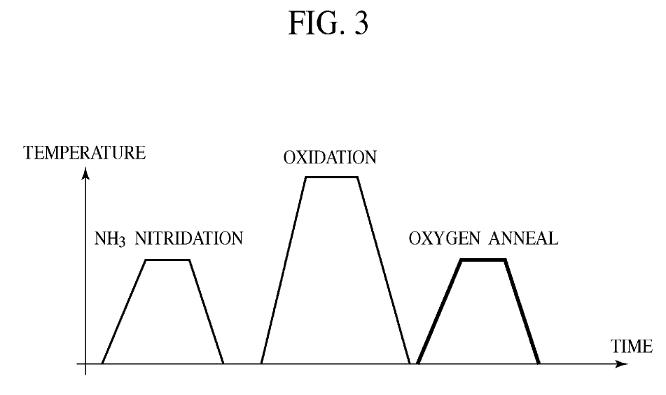

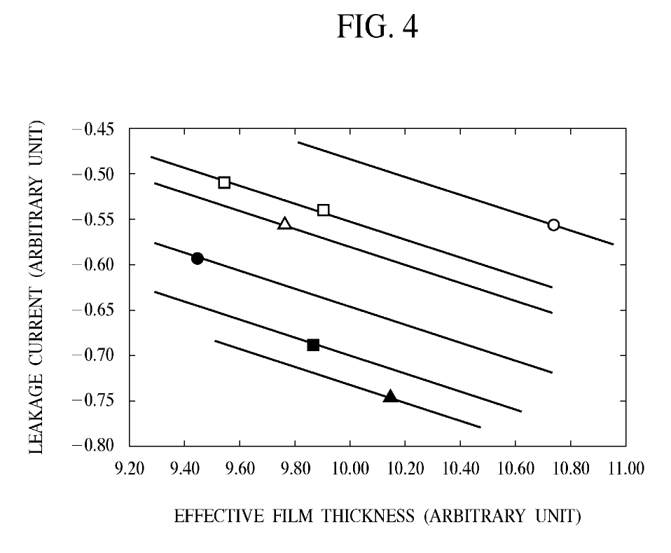

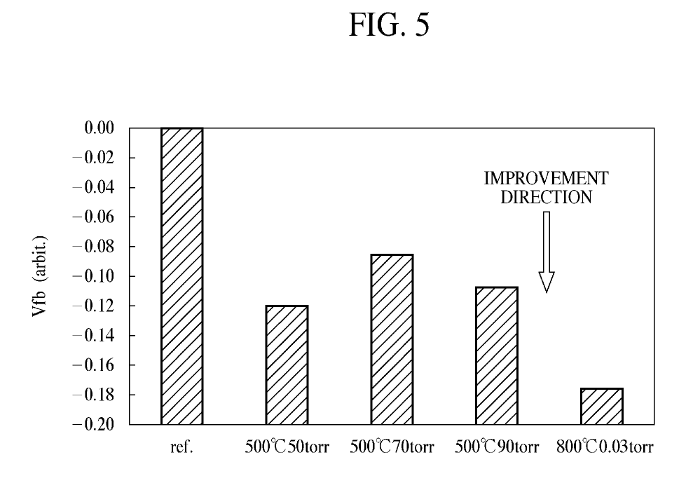

FIGS. 1A-2C are sectional views illustrating a method of manufacturing a semiconductor device according to the present embodiment. FIG. 3 is a view illustrating the temperature profile of the process for forming the gate insulating film. FIG. 4 is a graph illustrating the relationships between the gate leakage current and the effective film thickness converted to silicon oxide film of samples with oxygen anneal and samples without oxygen anneal. FIG. 5 is a graph illustrating changes of the flat band voltage depending on the absence and presence of oxygen anneal.

First, in a silicon substrate 10, a device isolation film 12 for defining active regions is formed by, e.g., STI (Shallow Trench Isolation) method.

Then, n-type impurity is doped into the silicon substrate 10 in the active region by photolithography and ion implantation. This ion implantation includes well implantation, channel stop implantation, channel implantation, etc. Thus, an n-well 14 is formed in the silicon substrate 10 in the active region (FIG. 1A).

Next, thermal nitridation processing using, e.g., ammonia (NH₃) is made at, e.g., a temperature of 500° C.-900° C. to form a silicon nitride film 16 of, e.g., a 0.3-1.5 nm-thickness on the active region of the silicon substrate 10 (FIG. 1B). To form the silicon nitride film 16, nitridation processing using ammonia plasma may be used.

Next, by, e.g., thermal oxidation using, e.g., N₂O gas, the silicon nitride film 16 formed on the active region is thermally oxidized to change the silicon nitride film 16 into a silicon oxynitride film of, e.g., a 0.3-1.5 nm-thickness. Thus, a gate insulating film 22 of the silicon oxynitride film is formed (FIG. 1C). As the oxidation conditions for the silicon nitride film 16, the oxidation temperature may be, e.g., 800° C.-1100° C., and the N₂O partial pressure may be, e.g., 0.1 Torr-760 Torr.

The above oxidation conditions are for making the thermal oxidation less oxidative so as to improve the controllability of the oxide film thickness, and defects due to oxygen lack might be introduced in the formed silicon oxynitride film and in the interface with the silicon substrate 10.

Then, thermal processing (oxygen anneal) is made in an oxygen-content atmosphere. This oxygen anneal supplements the oxygen lacks in the silicon oxynitride film and in the interface between the silicon oxynitride film and the silicon substrate 10, and the film quality of the silicon oxynitride film and the interface characteristics are improved.

This oxygen anneal is for introducing oxygen into the gate insulating film 22, but the conditions for the thermal processing are suitably set so that the substrate is not oxidized with the result that the film thickness of the gate insulating film 22 is increased. When the substrate is oxidized, and the film thickness of the gate insulating film 22 is increased, the MIS capacitance is decreased, and the transistor characteristics are degraded.

The inventors of the present application have investigated and confirmed the advantageous effects of the embodiment with the thermal processing temperature set at the range of 400° C.-850° C. and the oxygen partial pressure set at the range of 90 Torr-0.03 Torr corresponding to the thermal processing temperature range. The upper limit of the thermal processing temperature is 850° C., because when the thermal processing temperature exceeds 850° C., the oxygen partial pressure for suppressing the film thickness increase must be set at less than 0.03 Torr, its control is difficult, and the reproducibility is lowered. The lower limit of the thermal processing temperature is set at 400° C., because the conditions of the lowest temperature at which the inventors of the present application have confirmed the advantageous effects of the present invention is 400° C. and 90 Torr. The oxygen partial pressure is further increased, whereby the advantageous effects will be producible even further lower temperatures.

FIG. 3 is a graph illustrating the transient change of the processing temperature in the process of forming the gate insulating film 22 from forming the silicon nitride film 16 to forming the silicon oxynitride film. As illustrated in FIG. 3, the oxygen anneal temperature is almost equal to or higher than the nitridation temperature and is lower than the oxidization temperature.

Then, over the entire surface of the silicon substrate 10 with the gate insulating film 20 formed on, a polycrystalline silicon film of a 100 nm-thickness, for example, is deposited by, e.g., CVD method.

Then, the polycrystalline silicon film is patterned by photolithography and dry etching to form the gate electrode 24 of the polycrystalline silicon film on the gate insulating film 22 (FIG. 1C).

Next, with the gate electrode 24 as the mask, p-type impurity ions are implanted into the silicon substrate 10 in the active region to form impurity diffused regions 26 to be extension regions or LDD regions in the silicon substrate 10 on both sides of the gate electrode 24 (FIG. 1D).

Next, a silicon oxide film, for example, is deposited over the entire surface by, e.g., CVD method.

Then, the silicon oxide film is etched back by dry etching to form a sidewall insulating film 28 of silicon oxide film on the side wall of the gate electrode 24.

Then, with the gate electrode 24 and the sidewall insulating film 28 as the mask, p-type impurity ions are implanted into the silicon substrate 10 in the active region to form impurity diffused regions 30 in the silicon substrate 10 on both sides of the gate electrode 24 (FIG. 2A).

Then, the implanted impurity is activated by rapid thermal annealing to form source/drain regions 32 of the impurity diffused regions 26, 30 (FIG. 2B).

Next, as required, by salicide (self aligned silicide) process, a metal silicide film 34 is formed selectively on the gate electrode 24 and the source/drain regions 32 (FIG. 2C).

Thus, a p-channel MISFET including the gate insulating film 22 formed of silicon oxynitride film is completed.

FIG. 4 is a graph illustrating the relationships between the gate leakage current and the effective film thickness of various samples of the gate insulating film 24 prepared by forming a 1 nm-thickness silicon nitride film, thermally oxidizing the film in an N₂O atmosphere and then oxygen annealing the film under various conditions, which were measured by corona charge method.

In the graph, the “o” marks indicate the sample without the oxygen anneal. The “A” marks indicate the sample subjected to the oxygen anneal under the conditions of 400° C. temperature and 90 Torr oxygen partial pressure. The “□” marks indicate the sample subjected to the oxygen anneal under the conditions of 45° C. temperature and 90 Torr oxygen partial pressure. The “” marks indicate the sample subjected to the oxygen anneal under the conditions of 500° C. temperature and 70 Torr oxygen partial pressure. The “▪” marks indicate the sample subjected to the oxygen anneal under the conditions of 800° C. temperature and 0.03 Torr oxygen partial pressure. The “▴” marks indicate the sample subjected to the oxygen anneal under the conditions of 850° C. temperature and 0.03 Torr oxygen partial pressure. The solid lines are regression straight lines under the respective conditions, based on the relationship between the leakage current and the effective film thickness generally confirmed (1 place/0.2 nm).

As illustrated in FIG. 4, the sample subjected to the oxygen anneal after the silicon oxynitride film had been formed could decrease the leakage current without increasing the effective film thickness of the gate insulating film 24. As the oxygen anneal temperature was higher, the leakage current could be decreased.

FIG. 5 is a graph illustrating the flat band voltage (Vfb) of various samples of the gate insulating film 24 prepared by forming a 1 nm-thickness silicon nitride film, thermally oxidizing the silicon nitride film in an N₂O atmosphere and oxygen annealing the film under various conditions, which were measured by corona charge method.

In the graph, from the left are the sample without the oxygen anneal (ref), the sample subject to the oxygen anneal under the conditions of 500° C. temperature and 50 Torr oxygen partial pressure, the sample subjected to the oxygen anneal under the conditions of 500° C. and 70 Torr oxygen partial pressure, the sample subjected to the oxygen anneal under the conditions of 500° C. temperature and 90 Torr oxygen partial pressure, and the sample subjected to the oxygen anneal under the conditions of 800° C. temperature and 0.03 Torr oxygen partial pressure. In this graph, with reference to the flat band voltage of the sample without the oxygen anneal, the flat band voltages under the rest conditions are indicated. As the flat band voltage is larger in the negative direction, the shift amount of the flat band voltage is smaller. That is, the density of the fixed electric charge in the gate insulating film 22 is decreased.

As illustrated in FIG. 5, all the samples subjected to the oxygen anneal have the flat band voltage Vfb increased in the negative direction, and the shift amount of the flat band voltage could be decreased. As the oxygen anneal temperature was higher, the shift amount of the flat band voltage could be decreased.

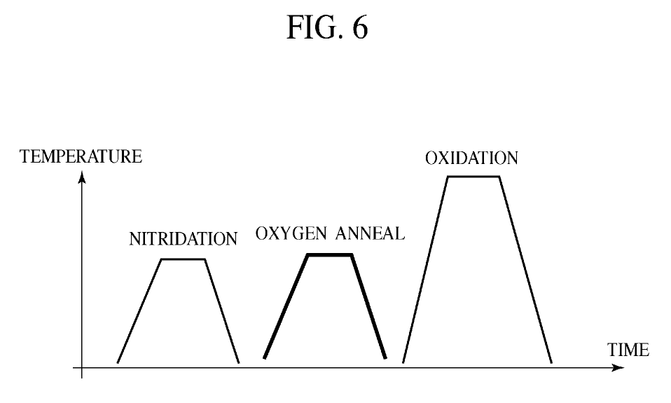

In the above examples, the oxygen anneal is made after the silicon nitride film has been oxidized, and the silicon oxynitride film has been formed. As illustrated in FIG. 6, for example, it is also effective to make the oxygen anneal after the silicon nitride film 16 has been formed and before the oxidation processing. The oxygen anneal is made before the oxidation processing, whereby oxygen can be introduced in advance in the interface between the silicon substrate 10 and the silicon nitride film 16, and the film quality of the silicon oxynitride film formed thereafter can be improved. It is also possible to make the oxygen anneal before the oxidation processing, and the oxygen anneal is also made after the oxidation processing.

As described above, according to the present embodiment, in forming the gate insulating film of the silicon oxynitride film by thermally nitridizing and thermally oxidizing the silicon substrate, after the thermal oxidization processing, thermal processing which is free from the film thickness increase due to the oxidation of the silicon substrate is made in an oxygen atmosphere to thereby supplement oxygen lack in the interface between the silicon nitride oxide film and the silicon substrate or in the silicon nitride oxide film, whereby the film quality and the interface characteristics of the silicon oxynitride film can be improved without increasing the effective film thickness of the gate insulating film.

### A Second Embodiment

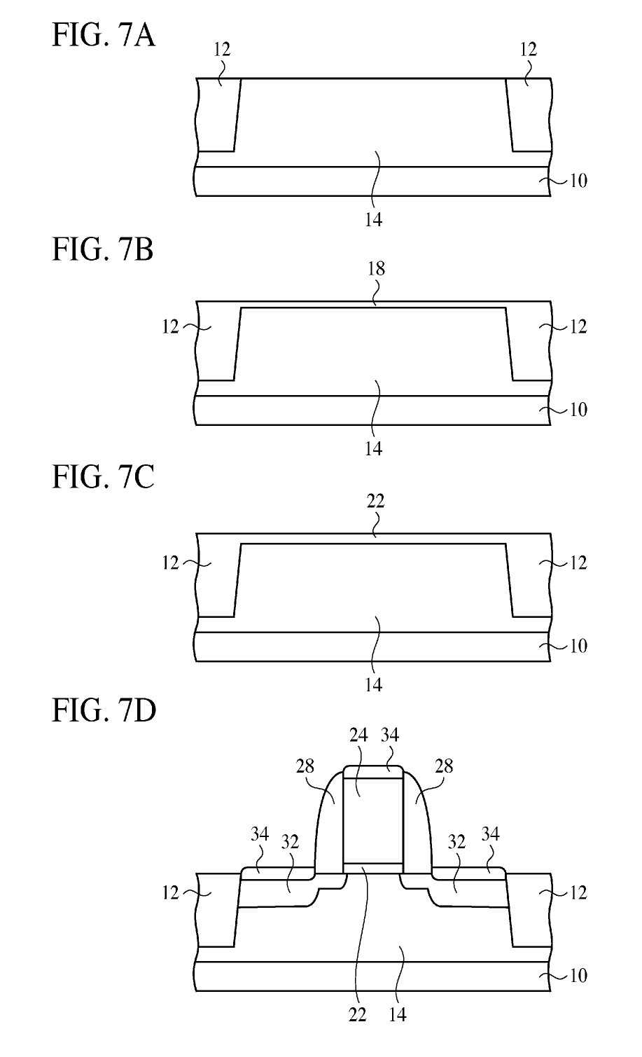

The method of manufacturing the semiconductor device according to a second embodiment will be explained with reference to FIGS. 7A to 10.

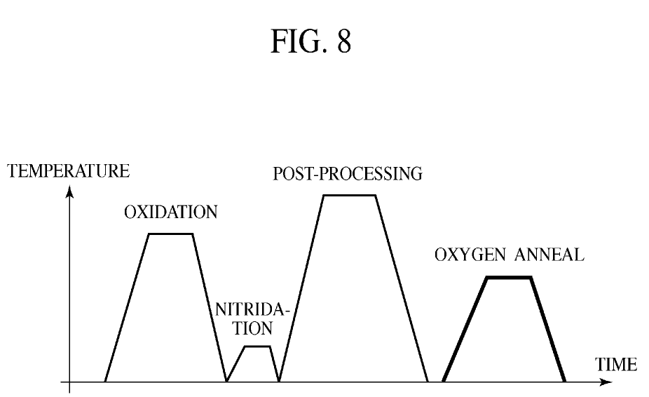

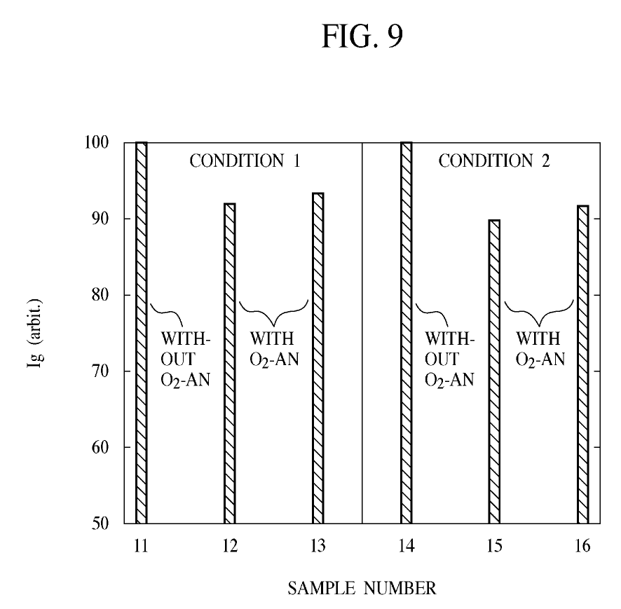

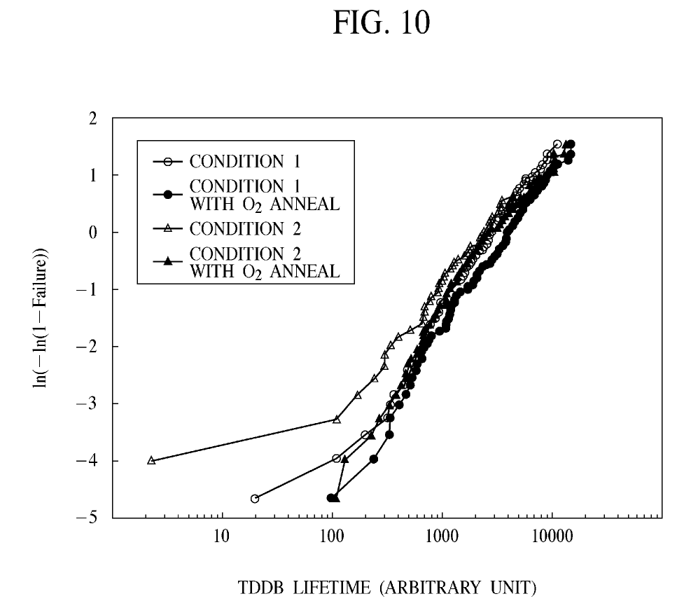

FIGS. 7A-7D are sectional views illustrating the method of manufacturing the semiconductor device according to the present embodiment. FIG. 8 is a view illustrating the temperature profile of the process for forming the gate insulating film. FIG. 9 is a graph illustrating changes of the gate leakage current depending on the absence and presence of oxygen anneal. FIG. 10 is a graph illustrating the cumulative probability distribution of the TDDB lifetimes of the gate insulating films.

First, a device isolation film 12 for defining active regions is formed in a silicon substrate 10 by, e.g., STI (Shallow Trench Isolation) method.

Then, n-type impurity is doped into the silicon substrate 10 in the active region by photolithography and ion implantation. This ion implantation includes well implantation, channel stop implantation, channel implantation, etc. Thus, an n-well 14 is formed in the silicon substrate 10 in the active region (FIG. 7A).

Next, by, e.g., thermal oxidation method, a silicon oxide film 18 of, e.g., a 0.9-1.3 nm-thickness is formed on the active region of the silicon substrate (FIG. 7B). The silicon oxide film 18 is formed by oxidizing the silicon substrate 10 in, e.g., a dry oxygen atmosphere at 850° C.-950° C.

The above oxidation conditions are for making the thermal oxidation less oxidative so as to improve the controllability of the oxide film thickness, and defects due to oxygen lack might be introduced in the formed silicon oxide film 18 and in the interface with the silicon substrate 10.

Then, the silicon oxide film 18 is nitridized by e.g., thermal nitridation or nitridation method using plasma ions to change the silicon oxide film 18 into a silicon oxynitride film of, e.g., a 0.9-1.7 nm-thickness. Thus, a gate insulating film 22 of silicon oxynitride film is formed (FIG. 7C). As the nitridation process for the silicon oxide film 18, for example, thermal NH₃ nitridation of not less than 500° C., nitridation using nitrogen plasma can be used.

Then, to supplement the oxygen lack after the nitridation, thermal processing as the post-thermal processing is made. This thermal processing is made at a higher temperature than the oxidation conditions for forming the silicon oxide film 18 and under the conditions which are less oxidative than the conditions for forming the silicon oxide film 18. The thermal processing is made less oxidative so as to suppress the decrease of the capacitance due to the film thickness increase. The thermal processing is made at a higher temperature so as to form stronger Si—O bonds to thereby improve the reliability of the gate insulating film 22.

Next, thermal processing (oxygen anneal) is made in an oxygen-content atmosphere. This oxygen anneal supplements oxygen lacks (defects which have not been removed by the thermal processing as the post-processing described above) in the silicon oxynitride film and in the interface with the silicon substrate 10 are supplemented, and the film quality of the silicon oxynitride film is improved.

This oxygen anneal is the processing for introducing oxygen into the gate insulating film 22, but the conditions for the thermal processing are suitably set not to oxidize the substrate resultantly to increase the film thickness of the gate insulating film 22. This is because when the substrate is oxidized, and the film thickness of the gate insulating film 22 is increased, the MIS capacitance is decreased, and the transistor characteristics are degraded.

The inventors of the present application have investigated and confirmed the advantageous effects of the embodiment with the thermal processing temperature set at the range of 400° C.-850° C. and the oxygen partial pressure set at the range of 90 Torr-0.03 Torr corresponding to the thermal processing temperature range. The upper limit of the thermal processing temperature is 850° C., because when the thermal processing temperature exceeds 850° C., the oxygen partial pressure for suppressing the film thickness increase must be set at less than 0.03 Torr, its control is difficult, and the reproducibility is lowered. The lower limit of the thermal processing temperature is set at 400° C., because the conditions of the lowest temperature at which the inventors of the present application have confirmed the advantageous effects of the present invention is 400° C. and 90 Torr. The oxygen partial pressure is further increased, whereby the advantageous effects will be producible even further lower temperatures.

FIG. 8 is a graph of the transient change of the processing temperature in the process of forming the gate insulating film 22 from forming the silicon oxide film 18 to forming the silicon oxynitride film. As shown n FIG. 8, the oxygen anneal temperature is almost equal to or higher than the nitridation temperature and is lower than the oxidization temperature and the post-processing temperature.

Then, in the same way as in, e.g., the method of manufacturing the semiconductor device according to the first embodiment illustrated in FIG. 1D to FIG. 2C, the gate electrode 24, the sidewall insulating film 28, the source/drain regions 32, the silicide film 34, etc. are formed (FIG. 7D).

Thus, a p-channel MISFET including the gate insulating film 22 formed of silicon oxynitride film is completed.

FIG. 9 is a graph illustrating the relationships of the gate leakage current between samples of the gate insulating film formed without the oxygen anneal and samples of the gate insulating film formed with the oxygen anneal. In the graph, the samples prepared under Condition 1 and the samples prepared under Condition 2 are different in the nitridation conditions for the silicon oxide film 18 in the step of FIG. 7C. Sample No. 11 and 14 are samples without the oxygen anneal (without O₂-AN), and Sample No. 12, 13, 15, 16 are samples with the oxygen anneal (with O₂-AN).

As shown in FIG. 9, the samples with the oxygen anneal could reduce the gate leakage current by about 10% in comparison with the samples without the oxygen anneal even with the silicon oxynitride film as the base formed under either of Conditions 1 and 2.

FIG. 10 is a graph illustrating the TDDB lifetimes of the samples of the gate insulating film formed without the oxygen anneal and the samples of the gate insulating film formed with the oxygen anneal, which were Weibull plotted. In the graph, the “o” marks and the “Δ” marks indicate the samples without the oxygen anneal, and the “” marks and the “▴” marks indicate the samples with the oxygen anneal. The samples prepared under Condition 1 and the samples prepared under Condition 2 are different in the nitridation conditions of the silicon oxide film 18 in the step of FIG. 7C.

As illustrated in FIG. 10, the samples with the oxygen anneal could improve the TDDB lifetime in comparison with the samples without the oxygen anneal even when the silicon oxynitride film as the base was formed under different nitridation conditions. The B-mode defect could be reduced.

As described above, according to the present embodiment, in forming the gate insulating film of the silicon oxynitride film by thermally oxidizing and thermally nitridizing the silicon substrate, after the thermal nitridization processing, thermal processing which is free from the film thickness increase due to the oxidation of the silicon substrate is made in an oxygen atmosphere to thereby supplement oxygen lack in the interface between the silicon nitride oxide film and the silicon substrate or in the silicon nitride oxide film, whereby the film quality and the interface characteristics of the silicon oxynitride film can be improved without increasing the effective film thickness of the gate insulating film.

### A Third Embodiment

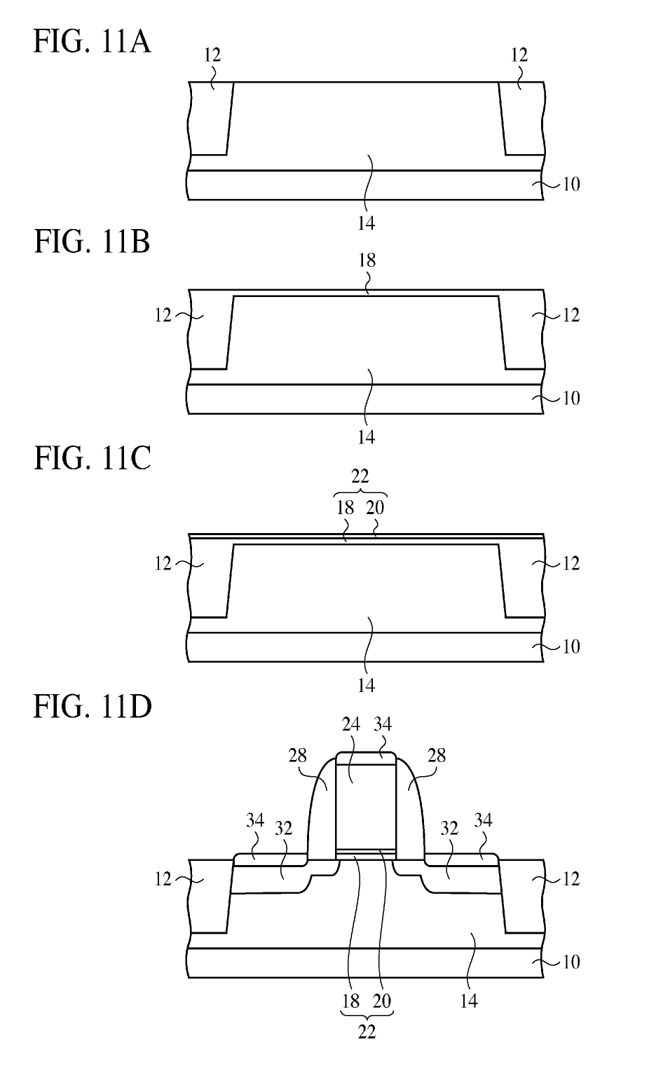

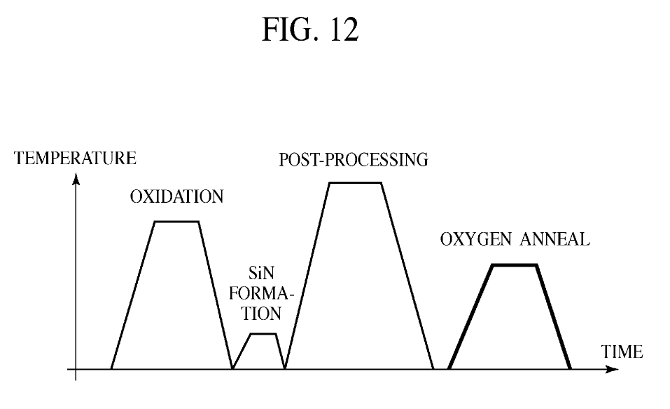

The method of manufacturing the semiconductor device according to a third embodiment will be explained with reference to FIGS. 11A to 12.

FIGS. 11A-11D are sectional views illustrating a method of manufacturing a semiconductor device according to the present embodiment. FIG. 12 is a view illustrating the temperature profile of the process for forming the gate insulating film.

First, a device isolation film 12 for defining active regions is formed in a silicon substrate 10 by, e.g., STI (Shallow Trench Isolation) method.

Next, n-type impurity is doped into the silicon substrate 10 in the active region by photolithography and ion implantation. This ion implantation includes well implantation, channel stop implantation, channel implantation, etc. Thus, an n-well 14 is formed in the silicon substrate 10 in the active region (FIG. 11A).

Then, a silicon oxide film 18 of, e.g., a 0.7-1.5 nm-thickness is formed on the active region of the silicon substrate 10 by, e.g., thermal oxidation method (FIG. 11B). The silicon oxide film 18 is formed by oxidizing the silicon substrate 10 in a dry oxygen atmosphere at, e.g., 700° C.-1100° C.

The above oxidation conditions are for making the thermal oxidation less oxidative so as to improve the controllability of the oxide film thickness, and defects due to oxygen lack might be introduced in the formed silicon oxide film 18 and in the interface with the silicon substrate 10.

Then, a silicon nitride film 20 of a 0.3-1.5 nm-thickness, for example, is deposited over the silicon oxide film 18 by, e.g., CVD method. Thus, the gate insulating film 22 of the layer film of the silicon oxide film 18 and the silicon nitride film 20 is formed (FIG. 11C). As the growth conditions for the silicon nitride film 20, the raw material gas is, e.g., NH₃ and Si₂H₄ and SiH₂Cl₂, and the film forming temperature is, e.g., 450° C.-800° C.

Then, thermal processing as the post-processing is made in a nitrogen or an oxygen atmosphere at, e.g., 800° C.-1100° C.

Next, thermal processing (oxygen anneal) is made in an atmosphere containing oxygen. This oxygen anneal supplements oxygen lacks in the gate insulating film 22 and in the interface with the silicon substrate 10, and the film quality of the gate insulating film 22 is improved.

This oxygen anneal is for introducing oxygen into the gate insulating film 22, but the thermal processing conditions are suitably set so that the substrate is not oxidized, resultantly to increase the film thickness of the gate insulating film 22. When the substrate is oxidized, and the film thickness of the gate insulating film 22 is increased, the MIS capacitance is decreased, and the transistor characteristics are degraded.

The inventors of the present application have investigated and confirmed the advantageous effects of the embodiment with the thermal processing temperature set at the range of 400° C.-850° C. and the oxygen partial pressure set at the range of 90 Torr-0.03 Torr corresponding to the thermal processing temperature range. The upper limit of the thermal processing temperature is 850° C., because when the thermal processing temperature exceeds 850° C., the oxygen partial pressure for suppressing the film thickness increase must be set at less than 0.03 Torr, its control is difficult, and the reproducibility is lowered. The lower limit of the thermal processing temperature is set at 400° C., because the conditions of the lowest temperature at which the inventors of the present application have confirmed the advantageous effects of the present invention is 400° C. and 90 Torr. The oxygen partial pressure is further increased, whereby the advantageous effects will be producible even further lower temperatures.

FIG. 12 illustrates the processing temperatures of forming the gate insulating film 22 from forming the silicon oxide film 18 to the oxygen annealing. As illustrated in FIG. 12, the oxygen anneal temperature is almost equal to or higher than the deposition temperature of the silicon nitride film 20 and is lower than the oxidation temperature and the post-processing temperature.

Then, in the same way as in, e.g., the method of manufacturing the semiconductor device according to the first embodiment illustrated in FIGS. 1D to 2C, the gate electrode 24, the sidewall insulating film 28, the source/drain regions 32, the silicide film 34, etc. are formed (FIG. 11D).

Thus, a p-channel MISFET including the gate insulating film 22 formed of the silicon oxide film 18 and the silicon nitride film 20 is completed.

The gate leakage current was measured on the thus-formed p-channel MISFET. The sample subjected to the oxygen anneal of the present embodiment could reduce the gate leakage current to about 80%.

As described above, according to the present embodiment, in forming the gate insulating film of the layer film of the silicon oxide film and the silicon nitride film, after depositing the silicon nitride film, thermal processing which is free from the film thickness increase due to the oxidation of the silicon substrate is made in an oxygen atmosphere to thereby supplement oxygen lack in the gate insulating film or in the interface between the gate insulating film and the silicon substrate, whereby the film quality and the interface characteristics of the gate insulating film can be improved without increasing the effective film thickness of the gate insulating film.

### Modified Embodiments

The above-described embodiments can cover other various modifications.

For example, in the first embodiment described above, the gate insulating film is formed by oxidizing the silicon substrate after nitridized, and in the second embodiment described above, the gate insulating film is formed by nitridizing the silicon substrate after oxidized, and in the third embodiment described above, the gate insulating film is formed by depositing silicon nitride film after the silicon substrate has been thermally oxidized. However, the structure and the basic manufacturing method of the gate insulating film are not limited to them.

In the above-described embodiments, for solving the problem of the silicon-based insulating film heavily containing nitrogen, i.e., reducing the decrease of the interface characteristics and the increase of charge trapping centers introduced into the film, oxygen anneal is made to thereby introduce oxygen into the film. It is applicable to methods for manufacturing various gate insulating films including silicon-based insulating films containing nitrogen.

Accordingly, it is applicable to not only the gate insulating films of the single layer structure of a silicon oxynitride film and the layer structure of a silicon oxide film and a silicon nitride film, but also to gate insulating films, etc. including high dielectric constant insulating films.

The various conditions used in the above-described embodiments, such as the raw material gases the oxidation temperature, nitridation temperature, the post-processing temperature, film thickness, etc., are not essential.

In the above-described embodiments, the method of manufacturing the semiconductor device is applied to manufacturing p-channel MISFETs. The above-described embodiments are similarly applicable also to n-channel MISFETs.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method of manufacturing a semiconductor device comprising:
nitridizing a silicon substrate with ammonia while heating the silicon substrate;
then heating the silicon substrate in an atmosphere containing nitrogen and oxygen to form a gate insulating film including a silicon-based insulating film containing nitrogen and oxygen;
then annealing the silicon substrate in an oxygen atmosphere; and
forming a gate electrode on the gate insulating film.

2. The method of manufacturing a semiconductor device according to claim 1, wherein
the nitridation with ammonia is made at a temperature of 500° C.-900° C.

3. The method of manufacturing a semiconductor device according to claim 1, wherein
the atmosphere containing nitrogen and oxygen is a N₂O atmosphere.

4. The method of manufacturing a semiconductor device according to claim 1, wherein
a temperature of the atmosphere containing nitrogen and oxygen is 800° C.-1000° C.

5. The method of manufacturing a semiconductor device according to claim 1, wherein
a temperature of the oxygen atmosphere is 400° C.-850° C.

6. The method of manufacturing a semiconductor device according to claim 1, wherein
an oxygen partial pressure of the oxygen atmosphere is 0.03 Torr-90 Torr.

7. The method of manufacturing a semiconductor device according to claim 1, further comprising, before nitridizing the silicon substrate with ammonia,
forming a silicon oxide film on the silicon substrate.

8. The method of manufacturing a semiconductor device according to claim 7, wherein
forming the silicon oxide film on the silicon substrate is made at a temperature of 850° C.-950° C.

9. A method of manufacturing a semiconductor device comprising:
nitridizing a silicon substrate with ammonia while heating the silicon substrate;
then annealing the silicon substrate in an oxygen atmosphere;
then heating the silicon substrate in an atmosphere containing nitrogen and oxygen to form a gate insulating film including a silicon-based insulating film containing nitrogen and oxygen; and
forming a gate electrode on the gate insulating film.

10. The method of manufacturing a semiconductor device according to claim 9, wherein
the nitridation with ammonia is made at a temperature of 500° C.-900° C.

11. The method of manufacturing a semiconductor device according to claim 9, wherein
the atmosphere containing nitrogen and oxygen is a N₂O atmosphere.

12. The method of manufacturing a semiconductor device according to claim 9, wherein
a temperature of the atmosphere containing nitrogen and oxygen is 800° C.-1000° C.

13. The method of manufacturing a semiconductor device according to claim 9, wherein
a temperature of the oxygen atmosphere is 400° C.-850° C.

14. The method of manufacturing a semiconductor device according to claim 9, wherein
an oxygen partial pressure of the oxygen atmosphere is 0.03 Torr-90 Torr.

15. The method of manufacturing a semiconductor device according to claim 9, further comprising, before nitridizing the silicon substrate with ammonia,
forming a silicon oxide film on the silicon substrate.

16. The method of manufacturing a semiconductor device according to claim 15, wherein
forming the silicon oxide film on the silicon substrate is made at a temperature of 850° C.-950° C.

17. A method of manufacturing a semiconductor device comprising:
forming a silicon oxide film over a silicon substrate;
forming a silicon nitride film over the silicon oxide film;
then annealing the silicon substrate in an oxygen atmosphere to form a gate insulating film including a silicon-based insulating film containing nitrogen and oxygen; and
forming a gate electrode on the gate insulating film,
annealing the silicon substrate being made at a temperature of 400° C.-850° C. in an atmosphere of a 0.03 Torr-90 Torr oxygen partial pressure.

18. The method of manufacturing a semiconductor device according to claim 17, further comprising, after forming the silicon nitride film and before forming the gate insulating film,
making a thermal processing in an atmosphere containing nitrogen or oxygen.

19. The method of manufacturing a semiconductor device according to claim 17, wherein
in forming the silicon nitride film, the silicon nitride film is formed by using NH₃ and Si₂H₄ or SiH₂Cl₂ as a raw material gas.
